(19) United States
(12) Patent Application Publication
(10) Pub. No.: US 2025/0370059 A1
(43) Pub. Date: Dec. 4, 2025

(54) METHOD AND APPARATUS FOR ESTIMATING ECO-FRIENDLY VEHICLE BATTERY DEGRADATION USING DRIVING ASSISTANCE FUNCTION OF A VEHICLE

(71) Applicants: HYUNDAI MOTOR COMPANY, Seoul (KR); KIA CORPORATION, Seoul (KR)

(72) Inventor: Yeol Mae Yeo, Hwaseong-si (KR)

(73) Assignees: HYUNDAI MOTOR COMPANY, Seoul (KR); KIA CORPORATION, Seoul (KR)

(21) Appl. No.: 18/975,569

(22) Filed: Dec. 10, 2024

(30) Foreign Application Priority Data
May 29, 2024 (KR) 10-2024-0070307

(51) Int. Cl. G01R 31/392; B60L 58/16; G01R 31/3835; G01R 31/389; G01R 31/396

(52) U.S. Cl. CPC G01R 31/392; B60L 58/16; G01R 31/3835; G01R 31/389; G01R 31/396

(57) ABSTRACT

A method and an apparatus for estimating eco-friendly vehicle battery degradation using a driving assistance function of a vehicle are disclosed. The method for estimating eco-friendly vehicle battery degradation includes: measuring a first voltage of each cell included in the battery during driving of the vehicle while discharging the battery of the vehicle at a preconfigured first current for a preconfigured time, determining a first resistance value of each cell based on the first current and the first voltage, and estimating degradation of the battery based on the first current and the first resistance value.

### CROSS-REFERENCE TO RELATED APPLICATION(S)

This application claims priority to Korean Patent Application No. 10-2024-0070307, filed on May 29, 2024, the entire contents of which are incorporated herein by reference.

### BACKGROUND

### 1. Field

The disclosure relates to a battery management system and, more specifically, to a method and apparatus for estimating battery degradation of a vehicle.

### 2. Description of the Prior Art

Eco-friendly vehicles, such as a hybrid electronic vehicle (HEV), a plug-in HEV (PHEV), and an electronic vehicle (EV), include built-in batteries corresponding to a storage device for storing electrical energy to drive motors, and specifically high-voltage batteries other than low-voltage batteries mounted in conventional internal combustion engine vehicles.

As the industry of eco-friendly vehicles grows, so does the industry that inspects, exchanges, and recycles the high-voltage batteries. Accordingly, a technology to accurately measure the degradation of batteries in battery packs, modules, or partial repair units is becoming increasingly important.

Battery degradation may be categorized into capacity degradation and output degradation, and the capacity degradation may be measured using a battery open circuit voltage (OCV), a current integration, a state of charge (SOC) in a battery management system, so as to estimate a state of health (SOH).

Conventionally, the output degradation of a battery has been estimated from current and resistance or polarization, but by these methods, it is difficult to accurately measure the output degradation of the battery.

The statements in this section merely provide background information related to the present disclosure and may not constitute prior art.

### SUMMARY

A technical aspect of the present disclosure is to identify an output characteristic according to degradation of an actual battery by using a driving assistance function of a vehicle, so as to accurately measure the output degradation of the battery.

Another technical aspect of the present disclosure is to accurately measure the output degradation of the battery, so as to easily determine a timing for inspection, exchange, and recycling of the battery.

The technical subjects pursued in the present disclosure may not be limited to the above-mentioned technical subjects, and other technical subjects which are not mentioned may be clearly understood from the following descriptions by those having ordinary skill in the art to which the present disclosure pertains.

According to an embodiment of the present disclosure, a method for estimating eco-friendly vehicle battery degradation includes: an operation of measuring a first voltage of each cell included in the battery during driving of the vehicle while discharging the battery of the vehicle at a preconfigured first current for a preconfigured time, an operation of determining a first resistance value of each cell based on the first current and the first voltage, and an operation of estimating degradation of the battery based on the first current and the first resistance value.

In one embodiment, the degradation estimation method may further include: an operation of determining whether it is possible to drive the vehicle while discharging the battery of the vehicle at the first current for a preconfigured time. In particular, the first voltage may be measured in response that it is possible to drive the vehicle while discharging the battery of the vehicle at the first current for the preconfigured time.

In one embodiment, the degradation estimation method may further include an operation of determining whether the vehicle satisfies a condition for entering a degradation diagnosis mode. The first voltage may be measured in response that the condition for entering the degradation diagnosis mode is satisfied.

In one embodiment, the degradation estimation method may further include: an operation of measuring a second voltage of each cell included in the battery during driving of the vehicle while discharging the battery of the vehicle at a second current acquired by increasing or decreasing a previously configured current of the battery by a predetermined rate or more for the preconfigured time, an operation of determining a second resistance value based on the second current and the second voltage, and an operation of estimating degradation of the battery based on an accumulated current from the first current to the second current and an accumulated resistance value from the first resistance value to the second resistance value.

In another embodiment, the degradation estimation method may further include: comparing a threshold with the number of times of increasing or decreasing the previously configured current of the battery by a predetermined rate or more; and in response that the number of times of increasing or decreasing the previously configured current of the battery by the predetermined rate or more is equal to or greater than the threshold, estimating degradation of the battery based on the accumulated current and resistance value.

Here, the degradation of the battery may be estimated by extracting a state of health (SOH) matching a combination of the first current and the first resistance value from a cell current-resistance table for SOH estimation.

In this case, degradation of a cell having a lowest state of health (SOH) may be determined as the degradation of the battery.

With respect to the degradation of the battery, if there is no value exactly matching the first current or the first resistance in the cell current-resistance table for SOH estimation, a SOH matching a most closely approximate value among values lower than the first current or the first resistance within a range of each current or resistance may be determined to be the SOH matching a combination of the first current and the first resistance.

If there are no other vehicles within a preconfigured distance from the front of the vehicle, a road is straight for at least a predetermined distance from a current location of the vehicle, or a road where the vehicle is driving is a section control road for a preconfigured distance or more from a current location of the vehicle, or in case of a combination thereof, it may be determined that it is possible to drive the vehicle while discharging the battery of the vehicle at the first current for the preconfigured time.

The condition for entering the degradation diagnosis mode may be determined to be satisfied in response that an autonomous driving mode or driving assistance mode is turned on for battery degradation diagnosis according to a user input or a schedule preconfigured in the vehicle.

According to an embodiment of the present disclosure, a degradation estimation apparatus includes: a sensor unit including a voltage sensor configured to detect a voltage of multiple cells forming a battery configured to store energy for driving a vehicle, and a battery management unit configured to measure a first voltage of each cell included in the battery during driving of the vehicle while discharging the battery at a preconfigured first current for a preconfigured time, determine a first resistance value of each cell based on the first current and the first voltage, and estimate degradation of the battery based on the first current and the first resistance value.

The battery management unit may determine whether it is possible to drive the vehicle while discharging the battery of the vehicle at the first current for a preconfigured time. In particular, the first voltage may be measured in response that it is possible to drive the vehicle while discharging the battery of the vehicle at the first current for the preconfigured time.

The battery management unit determines whether the vehicle satisfies a condition for entering the degradation diagnosis mode. In particular, the first voltage may be measured in response that the condition for entering the degradation diagnosis mode is satisfied.

The battery management unit may measure a second voltage of each cell included in the battery during driving of the vehicle while discharging the battery of the vehicle at a second current acquired by increasing or decreasing a previously configured current of the battery by a predetermined rate or more for the preconfigured time, determine a second resistance value based on the second current and the second voltage, and estimate degradation of the battery based on an accumulated current from the first current to the second current and an accumulated resistance value from the first resistance value to the second resistance value.

The battery management unit may compare a threshold with the number of times of increasing or decreasing the previously configured current of the battery by a predetermined rate or more. In response that the number of times of increasing or decreasing the previously configured current of the battery by the predetermined rate or more is equal to or greater than the threshold, the battery management unit may estimate degradation of the battery based on the accumulated current and resistance value.

Here, the degradation of the battery may be estimated by extracting a state of health (SOH) matching a combination of the first current and the first resistance value from a cell current-resistance table for SOH estimation.

In this case, the degradation of the battery is determined by degradation of a cell with a lowest state of health (SOH) among the multiple cells.

With respect to the degradation of the battery, when there is no value exactly matching the first current or the first resistance in the cell current-resistance table used for SOH estimation, a SOH matching a most closely approximate value among values lower than the first current or the first resistance within a range of each current or resistance may be determined to be the SOH matching a combination of the first current and the first resistance.

When there are no other vehicles within a preconfigured distance from the front of the vehicle, a road is straight for at least a predetermined distance from a current location of the vehicle, or a road where the vehicle is driving is a section control road for a preconfigured distance or more from the current location of the vehicle, or in case of a combination thereof, it may be determined that it is possible to drive the vehicle while discharging the battery of the vehicle at the first current for the preconfigured time.

The condition for entering the degradation diagnosis mode may be determined to be satisfied in response that an autonomous driving mode or driving assistance mode is turned on for battery degradation diagnosis according to a user input or a schedule preconfigured in the vehicle.

As described above, various embodiments of the present disclosure may allow identifying an output characteristic according to degradation of an actual battery by using a driving assistance function of a vehicle so as to accurately measure the output degradation of the battery.

Furthermore, by accurately measuring the output degradation of the battery, the timing of inspection, exchange, and recycling of the battery may be easily determined.

Advantageous effects obtainable from the present disclosure may not be limited to the above mentioned effects, and other effects which are not mentioned may be clearly understood from the following descriptions by those skilled in the art to which the present disclosure pertains.

### BRIEF DESCRIPTION OF THE DRAWINGS

FIG. 1 is a block diagram schematically illustrating a battery degradation estimation apparatus according to an embodiment of the present disclosure; and

FIGS. 2A and 2B are flowcharts illustrating a battery degradation estimation method according to an embodiment of the present disclosure.

### DETAILED DESCRIPTION

Hereinafter, embodiments set forth herein are described in detail with reference to the accompanying drawings, and the same or similar elements are given the same and similar reference numerals regardless of figure numbers, so duplicate descriptions thereof are omitted. The terms “module” and “unit” used for the elements in the following description are given or interchangeably used in consideration of only the ease of writing the specification, and do not have distinct meanings or roles by themselves.

The term “unit” or “module” used in this specification signifies one unit that processes at least one function or operation, and may be realized by hardware, software, or a combination thereof. The operations of the method or the functions described in connection with the forms disclosed herein may be embodied directly in a hardware or a software module executed by a processor, or in a combination thereof.

Furthermore, in describing the embodiments set forth herein, a detailed description of known relevant technologies has been omitted when it is determined that the description may make the subject matter of the present disclosure obscure. In addition, it should be appreciated that the accompanying drawings are provided only for the sake of easy understanding of the embodiments set forth herein, and the technical idea of the present disclosure is not limited to the accompanying drawings and includes all modifications, equivalents, or alternatives falling within the spirit and scope of the present disclosure.

Terms including an ordinal number such as “a first” and “a second” may be used to describe various elements, but the elements are not limited to the terms. The above terms are used merely for the purpose of distinguishing one element from other elements.

In the case where an element is referred to as being “connected” or “coupled” to any other elements, it should be understood that not only the element may be directly connected or coupled to the other elements, but also another element may exist therebetween. Contrarily, in the case where an element is referred to as being “directly connected” or “directly coupled” to any other element, it should be understood that no other element exists therebetween.

A singular expression includes a plural expression unless they are definitely different in the context.

When a component, device, element, or the like of the present disclosure is described as having a purpose or performing an operation, function, or the like, the component, device, or element should be considered herein as being “configured to” meet that purpose or to perform that operation or function.

As used herein, the expression “include” or “have” are intended to specify the existence of mentioned features, numbers, steps, operations, elements, components, or combinations thereof, and should be construed as not precluding the possible existence or addition of one or more other features, numbers, steps, operations, elements, components, or combinations thereof.

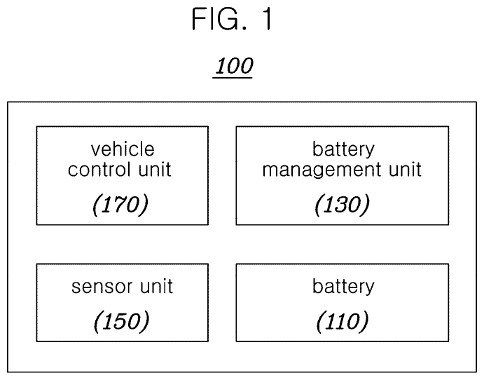

FIG. 1 is a block diagram schematically illustrating a battery degradation estimation apparatus according to an embodiment of the present disclosure.

Referring to FIG. 1, a battery degradation estimation apparatus according to the present embodiment includes a battery 110, a battery management unit 130, a sensor unit 150, and a vehicle control unit 170.

The battery 110 stores electrical energy for driving a vehicle and includes multiple cells each configured to store electrical energy.

The battery management unit 130 determines whether a vehicle satisfies a condition for entering a degradation diagnosis mode in a state in which the vehicle is ignited on (IG ON). When the condition for entering the degradation diagnosis mode is satisfied, in the degradation diagnosis mode, the battery management unit 130 determines whether it is possible to drive the vehicle while discharging the battery of the vehicle at a predetermined current for a preconfigured time.

Here, the battery management unit 130 measures a voltage of each cell included in the battery 110 during driving of the vehicle while discharging the battery of the vehicle at a preconfigured constant current for a preconfigured time. In particular, the battery management unit 130 determines a cell resistance value based on the measured voltage and stores the cell resistance value in a memory (not shown).

The condition for entering the degradation diagnosis mode may be determined to be satisfied when an autonomous driving mode or driving assistance mode is turned on for battery degradation diagnosis according to a user input or a schedule preconfigured in the vehicle. For example, the autonomous driving mode or driving assistance mode for battery degradation diagnosis may be implemented in the form of a smart cruise control (SCC). Under the smart cruise control, the preconfigured constant current may be determined according to a target vehicle (generally corresponding to a vehicle speed when entering/configuring a mode), but merely an example and is not necessarily limited thereto. However, the driving mode or driving assistance mode is to maintain a constant current, and thus it is desirable that the current does not fluctuate if the target speed is not maintained during mode activation.

The situations where it is possible to drive the vehicle while discharging the battery of the vehicle at the preconfigured constant current for the preconfigured time may include, for example, at least one of a case in which there is no other vehicles within a preconfigured distance from the front of the vehicle, a case in which a road is straight for at least a predetermined distance from a current location of the vehicle, a case in which a road where the vehicle is driving is a section control road for a preconfigured distance or more from a current location of the vehicle, or a case of a combination thereof.

In this case, a resistance value of each of the cells may be measured using a direct current internal resistance (DCIR) method.

The DCIR method is performed by applying charge and discharge pulses to a battery for a predetermined time and calculating and converting a voltage and current values changed at a time point of applying the pulses, using Ohm's law (R=I/V).

Here, the predetermined time may be commonly used time in the art for acquiring an internal resistance value by using the DCIR technique and may be, for example, 2 seconds or more.

In addition, the battery management unit 130 increases or decreases the discharge current by a predetermined rate or more from a previous discharge current, and determine whether the discharge current has been increased or decreased by a predetermined rate or more from a previous discharge current for a preconfigured number of times.

When the discharge current has been increased or decreased by a predetermined rate or more from a previous discharge current for the preconfigured number of times, the battery management unit 130 estimates degradation of the battery based on a current and voltage measured for the preconfigured number of times.

Meanwhile, when discharge current has not been increased or decreased by a predetermined rate or more from a previous discharge current for the preconfigured number of times, the battery management unit 130 determines whether it is possible to drive while discharging the battery or the vehicle at a preconfigured current that corresponds to a current increased or decreased by a predetermined rate or more from a previous discharge current for a preconfigured time.

If, as a result of the above determination, it is possible to drive the vehicle discharging the vehicle's battery at a preconfigured current for a preconfigured time, the following operations are repeatedly performed: driving the vehicle while discharging the battery of the vehicle at the preconfigured current for the preconfigured time and measuring a voltage of each cell, determining and storing a resistance value of the cell, increasing or decreasing the battery current of the vehicle by a predetermined rate or more compared to a previous discharge current, and determining whether the discharge current has been increased or decreased by the predetermined rate or more compared to the previous discharge current for a preconfigured number of times.

In one embodiment, the rate of the increased or decreased current may be a predetermined rate and may be, for example, 10% or more.

In one embodiment, the preconfigured number of times may be arbitrary and may be, for example, 2 times or more.

When the discharge current has been increased or decreased by a predetermined rate or more from a previous discharge current for the preconfigured number of times, the battery management unit 130 estimates degradation of the battery based on a current and voltage measured for the preconfigured number of times.

Here, the degradation of the battery may be estimated by extracting a state of health (SOH) matching a combination of the current of the battery and the resistance of the cell from the cell current-resistance table for SOH estimation.

For example, the SOH may be extracted using a cell-resistance table according to a current for each SOH as shown in Table 1 below.

TABLE 1

| | current | | | | | | | | | |
|---|---|---|---|---|---|---|---|---|---|---|
| SOH | 50 A | | 100 A | | 150 A | | 200 A | | 250 A | |
| 100% | 0.33 | (mΩ) | 0.5 | (mΩ) | 0.8 | (mΩ) | 1 | (mΩ) | 1.2 | (mΩ) |
| 95% | 0.4 | (mΩ) | 0.6 | (mΩ) | 0.9 | (mΩ) | 1.1 | (mΩ) | 1.3 | (mΩ) |
| 90% | 1.4 | (mΩ) | 0.7 | (mΩ) | 1 | (mΩ) | 1.2 | (mΩ) | 1.4 | (mΩ) |
| 85% | 2.4 | (mΩ) | 0.8 | (mΩ) | 1.1 | (mΩ) | 1.3 | (mΩ) | 1.5 | (mΩ) |
| 80% | 3.4 | (mΩ) | 0.9 | (mΩ) | 1.2 | (mΩ) | 1.4 | (mΩ) | 1.6 | (mΩ) |
| 75% | 4.4 | (mΩ) | 1 | (mΩ) | 1.3 | (mΩ) | 1.5 | (mΩ) | 1.7 | (mΩ) |
| 70% | 5.4 | (mΩ) | 1.1 | (mΩ) | 1.4 | (mΩ) | 1.6 | (mΩ) | 1.8 | (mΩ) |

Referring to Table 1, it is identified that by extracting a state of health (SOH) matching the current and the resistance of the cell measured from the cell current-resistance table for SOH estimation, the SOH of the cell may be measured. In this case, degradation of a cell having a lowest state of health (SOH) may be determined as the degradation of the entire battery.

For example, it may be identified that if the measured current is 50 A and the calculated resistance is 1.4 mΩ, the cell has a SOH of 90%.

Here, if there is no value exactly matching the current value or the resistance value in the cell current-resistance table for SOH estimation, a SOH matching a most closely approximate value, among values lower than the current value or the resistance value within a range of each current or resistance, may be determined to be the SOH.

In this case, with respect to the order of determination of each range, a current value may be determined and then a matched resistance value may be determined.

For example, in case that the measured current has a value of 60 A and the resistance has a value of 2 mΩ, a SOH of 90% having a value of 50 A based on a current and a value of 1.4 mΩ based on a resistance may be determined as the corresponding SOH.

Here, the battery management unit 130 may increase or decrease a discharging current of the battery by a predetermined rate compared to the previous discharging current to drive the vehicle while discharging the vehicle's battery for the preconfigured time, repeat the operation of calculating a resistance value for each cell included in the battery 110 and storing the calculated value in the memory predetermine number of times to determine the SOH matching the current-resistance multiple times, and when there is a SOH having determined the most times, determine the SOH having determined the most time as a final SOH value.

Meanwhile, there is no SOH having determined the most times, one of mean, median, maximum, and minimum values of the SOH may be selected and determined as the final SOH value.

The sensor unit 150 measures a voltage of the battery 110.

Here, the sensor part 150 may measure voltages of all cells included in the battery 110.

The vehicle control unit 170 controls the vehicle based on the output of the battery 110.

In this case, the vehicle control unit 170 receives information on degradation abnormality occurrence in a cell of the battery 110 from the battery management unit 130 and control the vehicle based on the information.

For example, in case of receiving information on degradation abnormality occurrence in a cell of the battery 110 from the battery management unit 130, the vehicle control unit 170 may gradually decrease a speed of the vehicle or control the vehicle to be evacuated to a safe place.

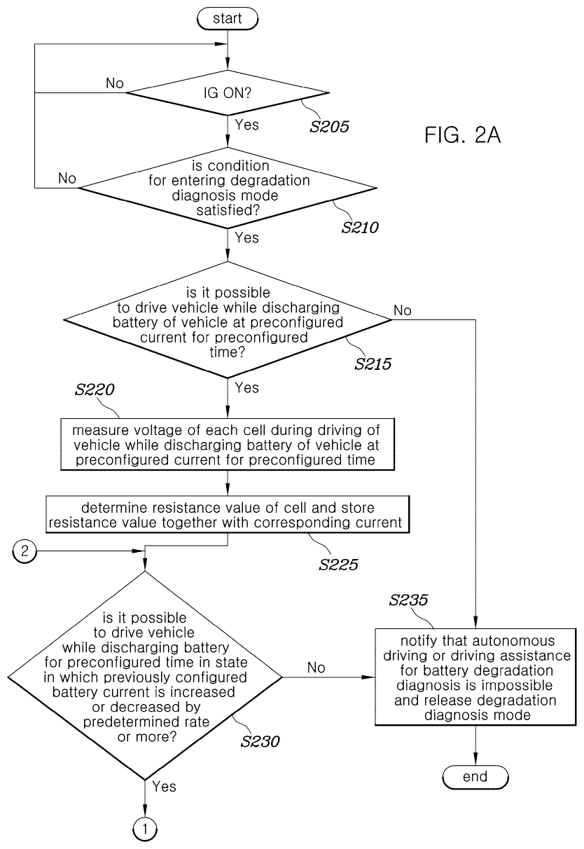

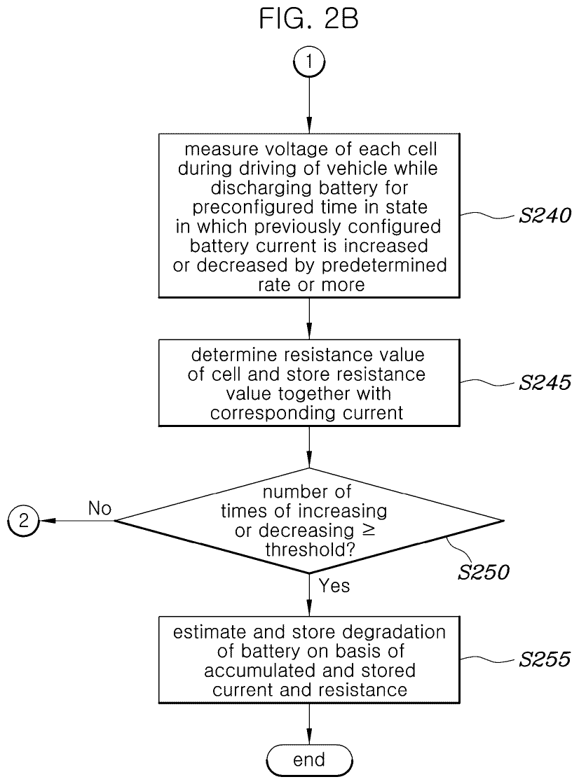

FIGS. 2A and 2B are flowcharts illustrating a battery degradation estimation method according to an embodiment of the present disclosure.

The battery degradation estimation method according to the present embodiment may be performed by the battery management unit 130 of the degradation diagnosis device 100 according to the embodiment of FIG. 1.

Referring to FIGS. 2A and 2B, the battery management unit 130 determines whether a vehicle is in an ignited on (IG ON) state (an operation S205), determine whether the vehicle satisfies a condition for entering a degradation diagnosis mode (an operation S210) when the vehicle is in the ignited on (IG ON) state, and when the vehicle satisfies the condition for entering the degradation diagnosis mode, in the degradation diagnosis mode, determine whether it is possible to drive the vehicle while discharging the battery of the vehicle at a predetermined current for a preconfigured time (an operation S215).

When as a result of the determination of operation S215, it is possible to drive the vehicle while discharging the battery at the preconfigured current for the preconfigured time, the battery management unit 130 measures a voltage of each cell included in the battery 110 during driving of the vehicle while discharging the battery at the preconfigured current for the preconfigured time (in an operation S220), and also determines a resistance value based on the measured voltage to be stored in a memory (not shown) together with the preconfigured current (in an operation S225).

The condition for entering the degradation diagnosis mode may be determined to be satisfied when an autonomous driving mode or driving assistance mode is turned on for battery degradation diagnosis according to a user input or a schedule preconfigured in the vehicle.

The situations where it is possible to drive the vehicle while discharging the battery of the vehicle at the preconfigured current for the preconfigured time may include, for example, at least one of a case in which there is no other vehicles within a preconfigured distance from the front of the vehicle, a case in which a road is straight for at least a predetermined distance from a current location of the vehicle, a case in which a road where the vehicle is driving is a section control road for a preconfigured distance or more from a current location of the vehicle, or a case of a combination thereof.

In one embodiment, a resistance value of each of the cells may be measured using a direct current internal resistance (DCIR) method.

The DCIR method is performed by applying charge and discharge pulses to a battery for a predetermined time and calculating and converting a voltage and current values changed at a time point of applying the pulses, using Ohm's law (R=I/V).

In this case, the preconfigured time may be arbitrary and, may be, for example, 2 seconds or more.

Furthermore, the battery management unit 130 determines whether it is possible to drive the vehicle while discharging the battery for the preconfigured time in a state in which the previously configured battery current is increased or decreased by a predetermined rate or more (in an operation S230).

When as a result of the determination of operation S230, it is possible to drive the vehicle while discharging the battery for the preconfigured time in a state in which the previously configured battery current is increased or decreased by a predetermined rate or more, during driving of the vehicle and discharging the battery at a current having been increased or decreased by a preconfigured certain rate or more for the preconfigured time, the battery management unit 130 measures a voltage of each cell included in the battery 110 (in an operation S240), and determines a resistance value based on the measured voltage to be stored in a memory (not shown) together with the preconfigured current (in an operation S245).

Furthermore, the battery management unit 130 determines whether the number of times the discharge current of the battery has been increased or decreased by a predetermined rate or more compared to a previous discharge current is equal to or greater than a threshold (in an operation S250), and when the number is equal to or greater than the threshold, estimates and stores degradation of the battery based on an accumulated and stored current and voltage (in an operation S255).

In one embodiment, the rate of the increased or decreased current may be a predetermined rate and may be, for example, 10% or more.

In one form, the preconfigured number of times may be arbitrary and may be, for example, 2 times or more.

Here, the degradation of the battery may be estimated by extracting a state of health (SOH) matching a combination of the current of the battery and the resistance of the cell from the cell current-resistance table for SOH estimation.

For example, the SOH may be extracted using a cell-resistance table according to a current for each SOH as shown in Table 1.

In this case, degradation of a cell having a lowest state of health (SOH) may be determined as the degradation of the entire battery.

For example, it may be identified that if the measured current is 50 A and the calculated resistance is 1.4 mΩ, the cell has a SOH of 90%.

Here, if there is no value exactly matching the current value or the resistance value in the cell current-resistance table for SOH estimation, a SOH matching a value lower than the calculated resistance value or the measured current for each section may be determined to be the SOH.

In this case, with respect to the order of determination of each section, a current value may be determined and then a matched resistance value may be determined.

For example, in case that the measured current has a value of 60 A and the resistance has a value of 2 mΩ, an SOH of 90% having a value of 50 A based on a current and a value of 1.4 mΩ based on a resistance may be determined as the corresponding SOH.

Here, the battery management unit 130 may increase or decrease a discharging current of the battery by a predetermined rate compared to the previous discharging current to drive the vehicle while discharging the vehicle's battery for the preconfigured time, repeat the operation of calculating a resistance value for each cell included in the battery 110 and storing same in the memory predetermine number of times to determine the SOH matching the current-resistance multiple times, and when there is an SOH having determined the most times, determine the SOH having determined the most time as a final SOH value.

Meanwhile, there is no SOH having determined the most times, one of mean, median, maximum, and minimum values of the SOH may be selected and determined as the final SOH value.

Meanwhile, when as a result of the determination of operation S215 or operation S230, it is impossible to drive the vehicle while discharging the vehicle at the preconfigured current for the preconfigured time, the battery management unit 130 notify that autonomous driving or driving assistance for battery degradation diagnosis is impossible and releases the degradation diagnosis mode (in an operation S235).

Although not shown in FIGS. 2A and 2B, the vehicle control unit 170 may control the vehicle based on the information on degradation of the battery 110 stored in the memory.

For example, in case that the degradation of the battery 110 is equal to or less than a threshold, the vehicle control unit 170 may gradually decrease a speed of the vehicle or control the vehicle to be evacuated to a safe place.

According to the embodiments of the present disclosure described above, the output characteristic according to degradation of the actual battery may be identified using the driving assistance function of the vehicle so as to accurately measure the output degradation of the battery.

Furthermore, by accurately measuring the output degradation of the battery, the timing of inspection, exchange, and recycling of the battery may be easily determined.

The present disclosure as described above may be implemented as codes in a computer-readable medium in which a program is recorded. The computer-readable medium includes all types of recording devices in which data readable by a computer system are stored. Examples of the computer-readable medium include a hard disk drive (HDD), a solid state disk (SSD), a silicon disk drive (SDD), a ROM, a RAM, a CD-ROM, a magnetic tape, a floppy disk, an optical data storage device, and the like. Therefore, the above detailed description should not be construed in a limitative sense, but should be considered in an illustrative sense in all aspects. The scope of the present disclosure should not be determined by reasonable interpretation of the appended claims, and all changes and modifications within the equivalent scope of the present disclosure fall within the scope of the present disclosure.

What is claimed is:

1. A method for estimating eco-friendly vehicle battery degradation, the method comprising:
measuring a first voltage of each cell included in a battery during driving of a vehicle while discharging the battery of the vehicle at a preconfigured first current for a preconfigured time;
determining a first resistance value of each cell based on the first current and the first voltage; and
estimating degradation of the battery based on the first current and the first resistance value.

2. The method of claim 1, further comprising:
determining whether it is possible to drive the vehicle while discharging the battery at the first current for the preconfigured time,
wherein the first voltage is measured in response that it is possible to drive the vehicle while discharging the battery at the first current for the preconfigured time.

3. The method of claim 1, further comprising:
determining whether the vehicle satisfies a condition for entering a degradation diagnosis mode,
wherein the first voltage is measured in response that the condition for entering the degradation diagnosis mode is satisfied, and
wherein the condition for entering the degradation diagnosis mode is determined to be satisfied in response that an autonomous driving mode or a driving assistance mode is turned on for battery degradation diagnosis according to a user input or a schedule preconfigured in the vehicle.

4. The method of claim 1, further comprising:
measuring a second voltage of each cell included in the battery during driving of the vehicle while discharging the battery at a second current acquired by increasing or decreasing a previously configured current of the battery by a predetermined rate or more for the preconfigured time;
determining a second resistance value of each cell based on the second current and the second voltage; and
estimating degradation of the battery based on an accumulated current from the first current to the second current and an accumulated resistance value from the first resistance value to the second resistance value.

5. The method of claim 4, further comprising:
comparing a threshold with a number of times of increasing or decreasing the previously configured current of the battery by a predetermined rate or more; and
in response that the number of times of increasing or decreasing the previously configured current of the battery by the predetermined rate or more is equal to or greater than the threshold, estimating degradation of the battery based on the accumulated current and resistance value.

6. The method of claim 1, wherein the degradation of the battery is estimated by extracting a state of health (SOH) matching a combination of the first current and the first resistance value from a cell current-resistance table for SOH estimation.

7. The method of claim 6, wherein degradation of a cell having a lowest state of health (SOH) is determined as the degradation of the battery.

8. The method of claim 6, wherein with respect to the degradation of the battery, if there is no value exactly matching the first current or the first resistance in the cell current-resistance table for SOH estimation, a SOH matching a most closely approximate value among values lower than the first current or the first resistance within a range of each current or resistance is determined as the SOH matching a combination of the first current and the first resistance.

9. The method of claim 2, wherein in case that there are no other vehicles within a preconfigured distance from a front of the vehicle, a road is straight for at least a predetermined distance from a current location of the vehicle, or a road where the vehicle is driving is a section control road for a preconfigured distance or more from a current location of the vehicle, or in case of a combination thereof, it is determined to be possible to drive the vehicle while discharging the battery of the vehicle at the first current for the preconfigured time.

10. The method of claim 1, wherein the preconfigured first current is configured based on a target speed of an autonomous driving mode or driving assistance mode, and
the preconfigured time is configured considering a technique for determining the first resistance value of each cell.

11. An apparatus for estimating eco-friendly vehicle battery degradation, the apparatus comprising:
a sensor unit comprising a voltage sensor configured to detect a voltage of multiple cells forming a battery configured to store energy for driving a vehicle; and
a battery management unit configured to:
measure a first voltage of each cell included in the battery during driving of the vehicle while discharging the battery at a preconfigured first current for a preconfigured time;
determine a first resistance value of each cell based on the first current and the first voltage; and
estimate degradation of the battery based on the first current and the first resistance value.

12. The apparatus of claim 11, wherein the battery management unit is configured to determine whether it is possible to drive the vehicle while discharging the battery of the vehicle at the first current for the preconfigured time, and
the first voltage is measured in response that it is possible to drive the vehicle while discharging the battery of the vehicle at the first current for the preconfigured time.

13. The apparatus of claim 11, wherein the battery management unit is configured to determine whether the vehicle satisfies a condition for entering a degradation diagnosis mode,
the first voltage is measured in response that the condition for entering the degradation diagnosis mode is satisfied, and
the condition for entering the degradation diagnosis mode is determined to be satisfied in response that an autonomous driving mode or a driving assistance mode is turned on for battery degradation diagnosis according to a user input or a schedule preconfigured in the vehicle.

14. The apparatus of claim 11, wherein the battery management unit is configured to:
measure a second voltage of each cell included in the battery during driving of the vehicle while discharging the battery of the vehicle at a second current acquired by increasing or decreasing a previously configured current of the battery by a predetermined rate or more for the preconfigured time;
determine a second resistance value of each cell based on the second current and the second voltage; and
estimate degradation of the battery based on an accumulated current from the first current to the second current and an accumulated resistance value from the first resistance value to the second resistance value.

15. The apparatus of claim 14, wherein the battery management unit is configured to:
compare a threshold with a number of times of increasing or decreasing the previously configured current of the battery by a predetermined rate or more; and
in response that the number of times of increasing or decreasing the previously configured current of the battery is equal to or greater than the threshold, estimate degradation of the battery based on the accumulated current and resistance value.

16. The apparatus of claim 11, wherein the degradation of the battery is estimated by extracting a state of health (SOH) matching a combination of the first current and the first resistance value from a cell current-resistance table for SOH estimation.

17. The apparatus of claim 16, wherein the degradation of the battery is determined by degradation of a cell with a lowest state of health (SOH) among the multiple cells.

18. The apparatus of claim 16, wherein when there is no value exactly matching the first current or the first resistance in the cell current-resistance table used for SOH estimation, a SOH matching a most closely approximate value among values lower than the first current or the first resistance within a range of each current or resistance is determined as the SOH matching a combination of the first current and the first resistance.

19. The apparatus of claim 12, wherein when there are no other vehicles within a preconfigured distance from a front of the vehicle, a road is straight for at least a predetermined distance from a current location of the vehicle, or a road where the vehicle is driving is a section control road for a preconfigured distance or more from the current location of the vehicle, or in case of a combination thereof, it is determined to be possible to drive the vehicle while discharging the battery of the vehicle at the first current for the preconfigured time.

20. The apparatus of claim 11, wherein the preconfigured first current is configured based on a target speed of an autonomous driving mode or a driving assistance mode, and
the preconfigured time is configured considering a technique for determining the first resistance value of each cell.
